(19) United States
(12) Patent Application Publication
(10) Pub. No.: US 2014/0209972 A1
(43) Pub. Date: Jul. 31, 2014

(54) SEMICONDUCTOR DEVICE

(71) Applicant: DENSO CORPORATION, Kariya-city, Aichi-pref. (JP)

(72) Inventors: Masakiyo Sumitomo, Okazaki-city (JP); Shigemitsu Fukatsu, Okazaki-city (JP)

(73) Assignee: Denso Corporation, Kariya-city (JP)

(21) Appl. No.: 14/346,755

(22) PCT Filed: Oct. 18, 2012
(86) PCT No.: PCT/JP2012/006657

§ 371 Date: Mar. 24, 2014

(30) Foreign Application Priority Data
Nov. 2, 2011 (JP) 2011-241220

(51) Int. Cl. H01L 29/739

(52) U.S. Cl. CPC H01L 29/7397
USPC 257/140

(57) ABSTRACT

In a semiconductor device, gate electrodes in a first group are connected with a first gate pad and gate electrodes in a second group are connected with a second gate pad. The gate electrodes in the first group and the gate electrodes in the second group are controllable independently from each other through the first gate pad and the second gate pad. When turning off, after a turn-off voltage with which an inversion layer is not formed is applied to the gate electrodes in the second group, a turn-off voltage with which an inversion layer is not formed is applied to the gate electrodes in the first group.

### CROSS REFERENCE TO RELATED APPLICATION

The present disclosure is based on Japanese Patent Application No. 2011-241220 filed on Nov. 2, 2011, the disclosures of which are incorporated herein by reference.

### TECHNICAL FIELD

The present disclosure relates to a semiconductor device in which an insulated gate bipolar transistor (hereafter, referred to as IGBT) having a trench gate structure is formed.

### BACKGROUND ART

Conventionally, as one of semiconductor devices for power conversion, a semiconductor device used for an electronic device such as an industrial motor and in which an IGBT is formed has been known. A general semiconductor device in which an IGBT is formed is configured as follows.

Namely, an N⁻ type drift layer is formed above a P⁺ type semiconductor substrate that forms a collector layer, a P type base layer is formed in a surface portion of the N⁻ type drift layer, and an N⁺ type emitter layer is formed in a surface portion of the P type base layer. In addition, a plurality of trenches penetrating the P type base layer and the N⁺ type emitter layer to reach the N⁻ type drift layer extends in a stripe pattern. On a wall surface of each of the trenches, a gate insulation film and a gate electrode are successively formed. Accordingly, a trench gate including the trench, the gate insulation film, and the gate electrode is formed. Above the P type base layer and the N⁺ type emitter layer, an emitter electrode is provided through an interlayer insulation film. The P type base layer and the N⁺ type emitter layer are electrically connected with the emitter electrode through control holes formed in the interlayer insulation film. On a rear surface of the collector layer, a collector electrode electrically connected with the collector layer is provided.

In the semiconductor device, when a turn-on voltage, that is, a voltage that increases a voltage Vge between a gate and an emitter to be higher than a threshold voltage Vth of a metal oxide semiconductor (MOS) gate is applied to the gate electrode, inversion layers having N type is formed at portions in the P type base layer in contact with the gate insulation films in the trenches. Then, electrons flow from the N⁺ type emitter layer into the N⁻ type drift layer through the inversion layers and holes flow from the collector layer into the N⁻ type drift layer. Accordingly, a resistance value is reduced due to conductivity modulation and the semiconductor device becomes an on-state.

The above-described semiconductor device in which the IGBT is formed can achieve an on-voltage lower than a semiconductor device in which a metal-oxide-semiconductor field-effect transistor (MOSFET) is formed. However, recently, it is required to further reduce the on-voltage.

Therefore, for example, the patent document 1 discloses that a width of adjacent trenches is set to be very narrow, that is, from 0.55 nm to 0.3 μm.

In the semiconductor device, because the width of the adjacent trenches is narrow, when the semiconductor device is turned on, portions in the P type base layer that do not become inversion layers are the minimum. Thus, most of the holes that have flowed in the N⁻ type drift layer are accumulated in the N⁻ type drift layer, and the on-voltage can be reduced. However, in the semiconductor device in the patent document 1, there is a problem that a switching speed at turning off decreases because a large amount of holes are accumulated in the N⁻ type drift layer when turning on.

### PRIOR ART DOCUMENTS

### Patent Document

[Patent Document 1] JP-A-2007-43123 (corresponding to US 2007/0001263 A1)

### SUMMARY OF INVENTION

It is an object of the present disclosure to provide a semiconductor device that can increase a switching speed at turning off while reducing an on-voltage.

A semiconductor device according to an aspect of the present disclosure includes a collector layer, a drift layer, a base layer, a plurality of trenches, a plurality of gate insulation films, a plurality of electrode electrodes, a plurality of emitter layers, an emitter electrode, a collector electrode, a first gate pad, and a second gate pad.

The collector layer has a first conductivity-type. The drift layer has a second conductivity-type and is formed above the collector layer. The base layer has the first conductivity-type and is formed above the drift layer. The trenches penetrate through the base layer to reach the drift layer and extend in a predetermined direction. The gate insulation films are respectively formed on wall surfaces of the trenches. The gate electrodes are respectively formed on the gate insulation films and include the gate electrodes in a first group and the gate electrodes in a second group. The emitter layers have the second conductivity-type and are formed at side portions of the trenches in a surface portion of the base layer. The emitter electrode is electrically connected with the emitter layers. The collector electrode is electrically connected with the collector layer. The first gate pad is connected with the gate electrodes in the first group. The second gate pad is connected with the gate electrodes in the second group.

When a turn-on voltage with which inversion layers are formed at portions of the base layer in contact with the gate insulation films is applied to the gate electrodes, electric current flows between the emitter electrode and the collector electrode. The gate electrodes in the first group and the gate electrodes in the second group are controllable independently from each other through the first gate pad and the second gate pad. When the semiconductor device is turned off, after a turn-off voltage with which the inversion layers are not formed is applied to the gate electrodes in the second group, a turn-off voltage with which the inversion layers are not formed is applied to the gate electrodes in the first group.

When the semiconductor device is turned off, that is, when the turn-off voltage is applied to the gate electrodes in the first group, a period of time for pulling out holes or electrons accumulated in the drift layer can be shorten, and a switching speed can be improved.

### BRIEF DESCRIPTION OF DRAWINGS

The above and other objects, features and advantages of the present disclosure will become more apparent from the following detailed description made with reference to the accompanying drawings. In the drawings:

FIG. 1 is a cross-sectional view of a semiconductor device according to a first embodiment of the present disclosure;

FIG. 2 is a plan view illustrating an arrangement of gate electrodes in the semiconductor device illustrated in FIG. 1;

FIG. 3(a) is a diagram illustrating a state where a turn-on voltage is applied to a normal gate electrode and a control gate electrode in the semiconductor device, FIG. 3(b) is a diagram illustrating a state where the turn-on voltage is applied to the gate electrode and 0 V as a turn-off voltage is applied to the control gate electrode, and FIG. 3(c) is a diagram illustrating a state where the turn-on voltage is applied to the normal gate electrode, and a negative voltage as the turn-off voltage is applied to the control gate electrode;

FIG. 4 is a timing diagram at a time when the semiconductor device illustrated in FIG. 1 is turned off;

FIG. 5 is a circuit diagram when the semiconductor device illustrated in FIG. 1 is connected to a load;

FIG. 6 is a diagram illustrating a simulation result of a relationship between a switching speed and an electric current, and a relationship between a switching speed and a voltage of the semiconductor device in the circuit illustrated in FIG. 5;

FIG. 7 is a diagram illustrating a simulation result of a relationship between a time difference between a time at which a turn-off voltage is applied to control gate electrodes and a time at which the a turn-off voltage is applied to normal gate electrodes and losses; and

FIG. 8 is a cross-sectional view of a semiconductor device according to another embodiment of the present disclosure.

### EMBODIMENTS FOR CARRYING OUT INVENTION

### First Embodiment

A semiconductor device according to a first embodiment of the present disclosure will be described with reference to the drawings.

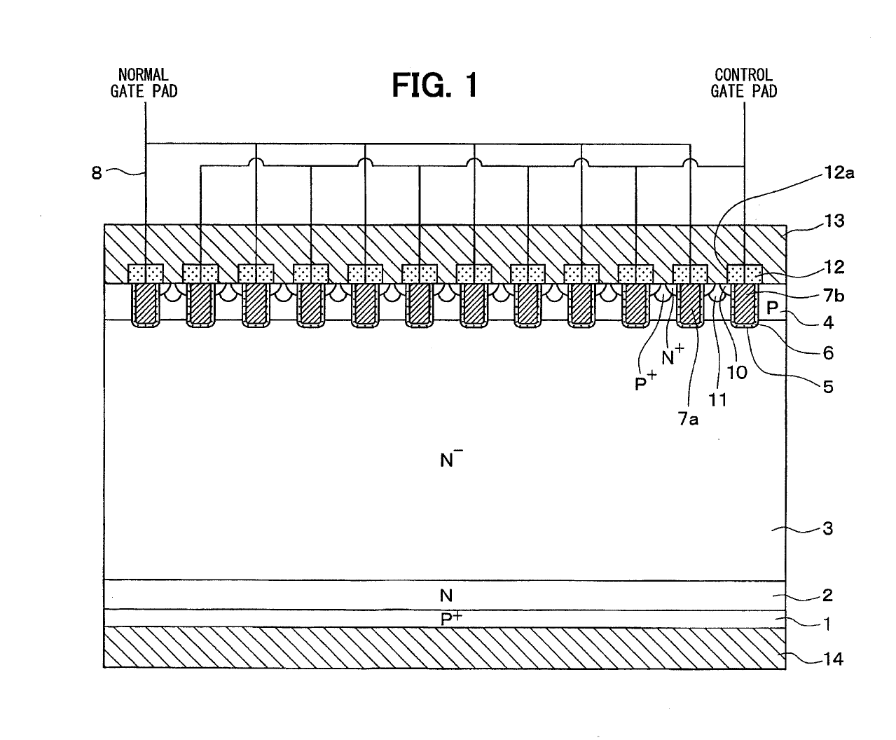

As illustrated in FIG. 1, an N type field stop layer (hereafter, referred to as an FS layer) 2 is formed above a main surface of a semiconductor substrate that forms a P⁺ type collector layer 1, and an N⁻ type drift layer 3 is formed above the FS layer 2. Although the FS layer 2 is not always necessary, the FS layer 2 is provided to restrict a spread of a depletion layer, thereby improving performance of a breakdown voltage and a stationary loss. At a surface portion of the N⁻ type drift layer 3, a P type base layer 4 is formed.

A plurality of trenches 5 penetrates through the P type base layer 4 to reach the N⁻ type drift layer 3. The trenches 5 are formed at predetermined intervals (pitches) and have a stripe structure extending in parallel in a predetermined direction (in FIG. 1, a direction perpendicular to a paper surface). Here, an example in which the trenches 5 have the stripe structure is described. However, the trenches 5 may also have a ring structure in which the trenches 5 extend in parallel and are pulled around at end portions.

Each of the trenches 5 is filled with a gate insulation film 6 and a normal gate electrode 7a or a control gate electrode 7b, thereby forming a trench gate structure. The gate insulation film 6 is formed to cover an inner wall surface of each of the trenches 5 and is made of, for example, a thermal oxide layer. The normal gate electrode 7a and the control gate electrode 7b are formed on the gate insulation film 6 and are made of, for example, polysilicon.

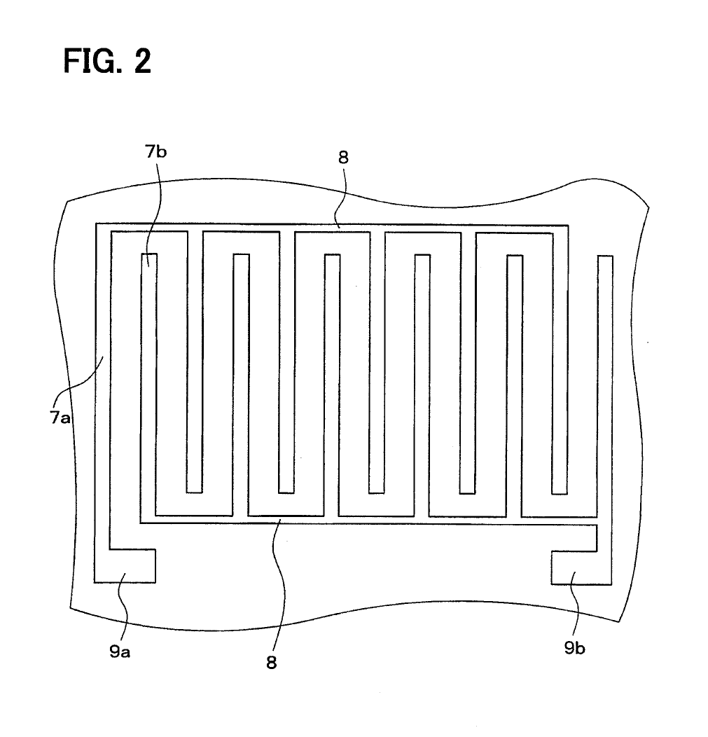

As illustrated in FIG. 1 and FIG. 2, the normal gate electrodes 7a are connected to a normal gate pad 9a through a gate wiring 8, and the control gate electrodes 7b are connected to a control gate pad 9b through a gate wiring 8. The normal gate pad 9a and the control gate pad 9b are applied with voltages (signals) independently from each other. In other words, the normal gate electrodes 7a and the control gate electrodes 7b are applied with voltages (signals) independently from each other. In the present embodiment, the normal gate electrodes 7a and the control gate electrodes 7b are alternately formed in a direction perpendicular to the extending direction of the trenches 5.

As illustrated in FIG. 1, in a surface portion of the P type base layer 4 disposed between the adjacent trenches 5, N⁺ type emitter layers 10 are formed to be in contact with side surfaces of the trenches 5, and P⁺ type body regions 11 are formed at positions separated from the side surfaces of the trenches 5. Specifically, the N⁺ type emitter layers 10 extend in a rod shape so as to be in contact with the side surfaces of the trenches 5 along the longitudinal direction of the trenches 5 and terminate inside ends of the trenches 5. Each of the P⁺ type body regions 11 is disposed between the two N⁺ type emitter layers 10, extends in a rod shape along the longitudinal direction of the trenches 5 (i.e., the N⁺ type emitter layers 10) and terminates inside the ends of the trenches 5. The N⁺ type emitter layers 10 and the P⁺ type body regions 11 have sufficiently higher concentrations than the P type base layer 4 and terminate in the P type base layer 4.

Above the P type base layer 4, an interlayer insulation film 12 made of, for example, boron phosphorous silicon glass (BPSG) is formed. In the interlayer insulation film 12, contact holes 12a are formed, and portons of the N⁺ type emitter layers 10 and the P⁺ type body regions 11 are exposed from the interlayer insulation film 12. Above the interlayer insulation film 12, an emitter electrode 13 is formed. The emitter electrode 13 is electrically connected to the N⁺ type emitter layers 10 and the P⁺ type body regions 11 through the contact holes 12a.

In addition, on a rear surface side of the P⁺ type collector layer 1, a collector electrode 14 electrically connected with the P⁺ type collector layer 1 is formed.

The above is the configuration of the semiconductor device according to the present embodiment. In the present embodiment, P type and P⁺ type correspond to a first conductivity-type, and N type and N⁺ type correspond to a second conductivity-type. In addition, the normal gate pad 9a corresponds to a first gate pad and the control gate pad 9b corresponds to a second gate pad. The normal gate electrodes 7a correspond to gate electrodes in a first group, and the control gate electrodes 7b correspond to gate electrodes in a second group.

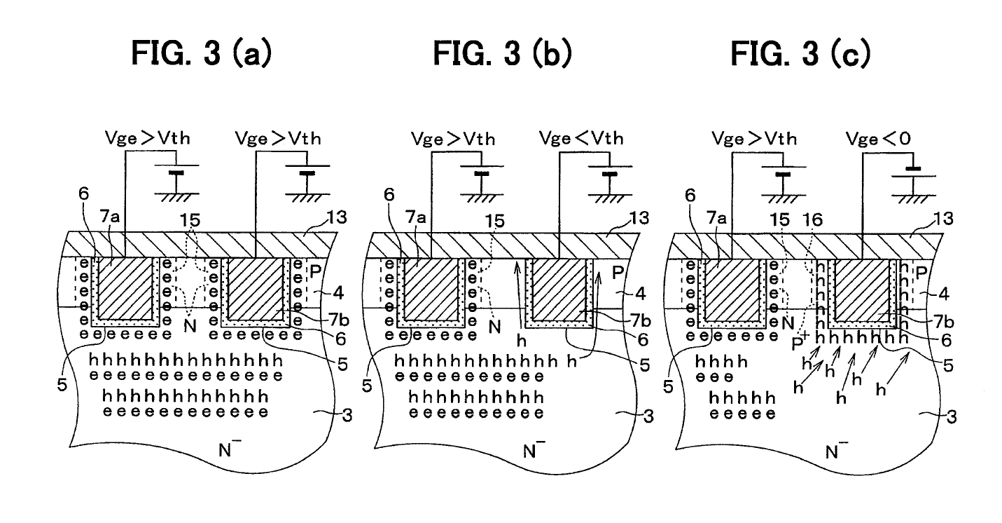

Next, an operation of the semiconductor device will be described with reference to FIG. 3(a) through FIG. 3(c).

In FIG. 3(a) through FIG. 3(c), the N⁺ type emitter layers 10, the P⁺ type body regions 11, and the interlayer insulation film 12 are omitted. Applying a turn-on voltage means applying a voltage that forms inversion layers at portions in the P type base layer 4 in contact with the gate insulation films 6, that is, increasing a voltage Vge between the gate and the emitter to be higher than a threshold voltage Vth of a MOS gate. Similarly, applying a turn-off voltage means applying a voltage that does not form the inversion layers at the portions in the P type base layer 4 in contact with the gate insulation films 6, that is, decreasing the voltage Vge between the gate and the emitter to be lower than the threshold voltage Vth of the MOS gate.

Firstly, a state when the semiconductor device is turned on will be described. As illustrated in FIG. 3(a), when the turn-on voltage is applied to the normal gate electrodes 7a and the control gate electrodes 7b through the normal gate pad 9a and the control gate pad 9b, inversion layers 15 having N type are formed at portions in the P type base layer 4 in contact with the gate insulation films 6 disposed in the trenches 5.

Then, electrons flow from the N⁺ type emitter layers into the N⁻ type drift layer 3 through the inversion layers 15 and holes flow from the P⁺ type collector layer 1 to the N⁻ type drift layer 3. Accordingly, the resistance value of the N⁻ type drift layer 3 decreases due to conductivity modulation, and the semiconductor device becomes the on-state.

A part of the holes that have flowed into the N⁻ type drift layer 3 is pulled out from the emitter electrode 13 through portions in the P type base layer 4 that do not become the inversion layers 15. Although the normal gate electrodes 7a and the control gate electrodes 7b are controllable independently from each other, the same voltage is applied when turning on. In other words, the on-voltage is similar to an on-voltage of a conventional semiconductor device.

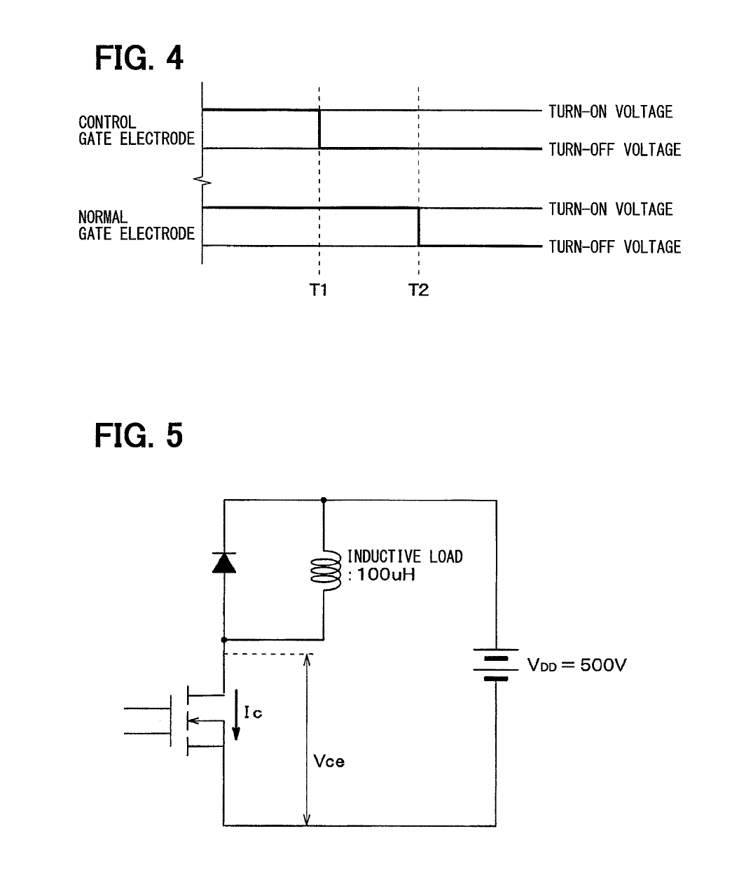

Next, a state when the semiconductor device is turned off will be described. As illustrated in FIG. 4, when the semiconductor device is turned off, after the turn-off voltage is applied to the control gate electrodes 7b through the control pad 9b at time point T1, the turn-off voltage is applied to the normal gate electrodes 7a through the normal gate pad 9a at time point T2.

In other words, as illustrated in FIG. 3(b), the semiconductor device is turned off after the turn-off voltage is applied to the control gate electrodes 7b, the inversion layers 15 at portions in the P type base layer 4 in contact with the gate insulation films 6 under the control gate electrodes 7b disappear, distribution channels in the P type base layer 4 spread, and a part of the holes accumulated in the N⁻ type drift layer 3 are pulled out from the emitter electrode 13. Thus, because a part of the holes that have flowed into the N⁻ type drift layer 3 are previously pulled out when the turned-off voltage is applied to the normal gate electrodes 7a, that is, when the semiconductor device is turned off, the switching speed can be increased.

In this case, as illustrated in FIG. 3(c), when a negative voltage is applied to the control gate electrodes 7b, the N type inversion layers 15 formed in the P type base layer 4 disappear and P⁺ type accumulation layers 16 are formed at regions where the inversion layers 15 have been formed. In other words, when the negative voltage is applied to the control electrode 7b, the holes that have flowed into the N⁻ type drift layer 3 easily flow to the accumulation layers 16, and the switching speed can be further increased.

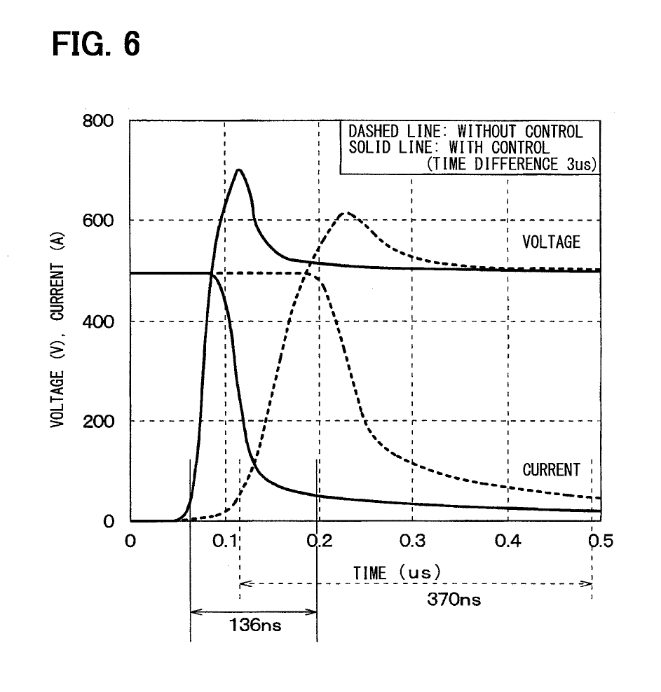

Here, effects obtained from a simulation by the inventors will be described. FIG. 5 is a circuit diagram when the above-described semiconductor device is connected to a load. In the semiconductor device used in FIG. 5, a power supply voltage is 500 V, an inductive load of a coil is 100 μH, an effective area to which electric current flows is 1 cm², and an interval of each of the trenches 5 is 0.5 μm. FIG. 6 is a simulation result illustrating a relationship between a switching speed and an electric current, and a relationship between a switching speed and a voltage of the semiconductor device in the circuit illustrated in FIG. 5. In FIG. 6, a case in which the turn-off voltage is applied to the normal gate electrodes 7a after the turn-off voltage is applied to the control gate electrodes 7b is illustrated by a solid line as with control, and a case in which the turn-off voltage is applied to each of the gate electrodes at the same time as in the conventional method is illustrated by a dashed line as without control. In a case with control, the turn-off voltage is applied to the control gate electrodes 7b 3 μs before the turn-off voltage is applied to the normal gate electrodes 7a. In FIG. 6, 0 V is applied as the turn-off voltage. In addition, in a case with control, a time point at which the turn-off voltage is applied to the normal gate electrodes 7a is set to 0. In a case without control, a time point at which the turn-off voltage is applied to each of the gate electrodes is set to 0.

As illustrated in FIG. 6, in the case with control, after about 60 ns from when the turn-off voltage is applied to the normal gate electrodes 7a, the voltage between the collector and the emitter increases to 50 V, which is 10% of the power supply voltage. Then, after about 196 ns, electric current decreases to 50 A, which is 10% of electric current that flows when turning on. In other words, a time from when the voltage between the collector and the emitter increases to 50 V to when the electric current decreases to 50 A is about 136 ns.

In contrast, in the case without control, the voltage between the collector and the emitter increases to 50 V about 110 ns after the turn-off voltage is applied to each of the gate electrodes. Then, electric current decreases to 50 A after about 480 ns. In other words, a time from when the voltage between the collector and the emitter increases to 50 V to when the electric current decreases to 50 A is 370 ns.

In this way, when the semiconductor device in which the effective area to which electric current flows is 1 cm² and the interval between each of the trenches 5 is 0.5 μm is applied to the above-described circuit, in a case where a time from when the voltage between the collector and the emitter increases to 50 V, which is 10% of the power supply voltage, to when the electric current decreases to 50 A, which is 10% at turning-on, is defined as a switching speed, the switching speed can be faster by 234 ns. In other words, the switching time can be reduced by about 63%.

Next, a time difference between the time point at which the turn-off voltage is applied to the control gate electrodes 7b and the time point at which the turn-off voltage is applied to the normal gate electrodes 7a will be described. As described above, in the case where the turn-off voltage is applied to the control gate electrodes 7b earlier than the normal gate electrodes 7a, the switching speed at turning off the semiconductor device can be faster. However, when the turn-off voltage is applied to the control gate electrodes 7b, the inversion layers 15 are not formed at the portions in the P type base layer 4 in contact with the gate insulation films 6 under the control gate electrodes 7b. Accordingly, electrons and holes flowing to the N⁻ type drift layer 3 reduce and the on-voltage increases. Thus, it is preferable that the time difference between the time point at which the turn-off voltage is applied to the control gate electrodes 7b and the time point at which the turn-off voltage is applied to the normal gate electrodes 7a is appropriately adjusted so as to increase the switching speed while restricting increase of the on-voltage. In other words, it is preferable that the sum of a conduction loss and a switching loss becomes the minimum.

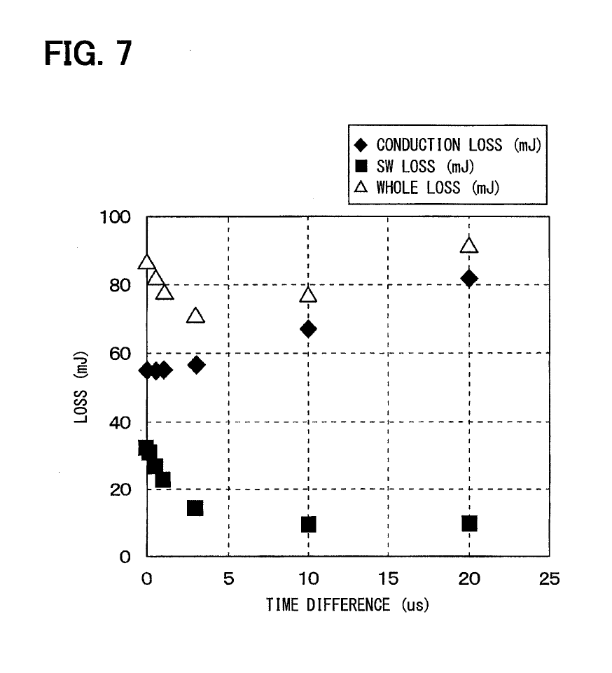

FIG. 7 is a simulation result illustrating a relationship between the time difference between the time point at which the turn-off voltage is applied to the control gate electrodes 7b and the time point at which the turn-off voltage is applied to the normal gate electrodes 7a and losses. Note that FIG. 7 is a simulation result using the semiconductor device in which the effective area to which electric current flows is 1 cm² and the interval of each of the trenches is 0.5 μm, and 0 V is applied as the turn-off voltage. The whole loss in FIG. 7 means the sum of the conduction loss and the switching loss.

As illustrated in FIG. 7, with increase of the time difference between the time point at which the turn-off voltage is applied to the control gate electrodes 7b and the turn-off voltage is applied to the normal gate electrodes 7a, the switching loss at turning off the semiconductor device decreases because the holes accumulated in the N⁻ type are discharged.

On the other hand, with increase of the time difference between the time point at which the turn-off voltage is applied to the control gate electrodes 7b and the turn-off voltage is applied to the normal gate electrodes 7a, the conduction loss at turning on the semiconductor device increases because the holes accumulated in the N⁻ type decrease.

The whole loss becomes the minimum when the time difference between the time point at which the turn-off voltage is applied to the control gate electrodes 7b and the time point at which the turn-off voltage is applied to the normal gate electrodes 7a is about 3 μs. Specifically, compared with a case where there is no time difference (a case where the time difference is 0) between the time point at which the turn-off voltage is applied to the control gate electrodes 7b and the time point at which the turn-off voltage is applied to the normal gate electrodes 7a, the switching loss can be reduced by 56% and the whole loss can be reduced by 19%. Thus, in the case of the semiconductor device in which the effective area to which electric current flows is 1 cm² and the interval between each of the trenches 5 is 0.5 μm, when the turn-off voltage is applied to the normal gate electrodes 7a 3 μm after the turn-off voltage is applied to the control gate electrodes 7b, the switching loss can be reduced while restricting increase of the conduction loss. Namely, the switching speed can be increased while reducing the on-voltage.

The time difference between the time point at which the turn-off voltage is applied to the control gate electrodes 7b and the turn-off voltage is applied to the normal gate electrodes 7a depends on the interval of each of the trenches 5 and the voltage applied as the turn-off voltage. Thus, it is preferable to change the time difference appropriately according to them. This is because the amount of holes accumulated in the N⁻ type drift layer changes with the interval of each of the trenches 5 and the amount of holes discharged from the N⁻ type drift layer 3 changes with the voltage applied as the turn-off voltage.

As described above, in the semiconductor device according to the present embodiment, the normal gate electrodes 7a and the control gate electrodes 7b are controllable independently from each other. The turn-off voltage is applied to the normal gate electrodes 7a to turn off the semiconductor device after the turn-off voltage is applied to the control gate electrodes 7b. In other words, when the semiconductor device is in the turn-on state, the semiconductor device is turned off after a part of the holes accumulated in the N⁻ type drift layer 3 is previously pulled out. Thus, when the semiconductor device is turned off, that is, when the turn-off voltage is applied to the normal gate electrodes 7a, a period of time for pulling out the holes accumulated in the N⁻ type drift layer 3 can be shorten, and the switching speed can be improved.

Because the normal gate electrodes 7a and the control gate electrodes 7b are alternately arranged in the direction parallel to the extending direction of the trenches 5, when the turn-off voltage is applied to the control gate electrodes 7b, the holes accumulated in the N⁻ type drift layer can be uniformly discharged. In other words, a situation that the large amount of holes are accumulated only in a specific region in the N⁻ type drift layer 3 can be restricted, and the amount of holes accumulated in the N⁻ type drift layer 3 can be uniformed as a whole. Thus, a situation that the switching speed is late at the specific region can be restricted, and the speed of turning off can be increased.

Although the above-described semiconductor device has the effects as long as the semiconductor device is a trench gate IGBT, it is preferable that the semiconductor device is applied to a device in which a large amount of holes are accumulated in the N⁻ type drift layer when the device is turned on. In other words, it is preferable that the above-described semiconductor device is applied to a so-called narrow-mesa type trench gate IGBT in which the distance between the each of the trenches 5 is very small.

### Other Embodiments

In the above-described embodiment, an example in which the normal gate electrodes 7a and the control gate electrodes 7b are alternately arranged in the direction perpendicular to the extending direction has been described. However, the normal gate electrodes 7a and the control gate electrodes 7b may also be arranged as follows.

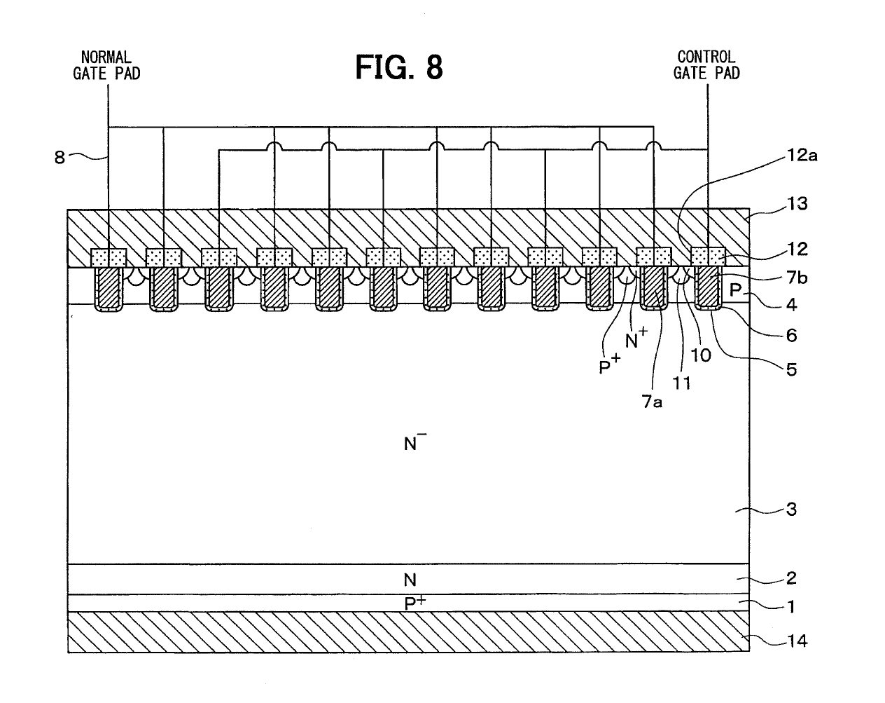

As illustrated in FIG. 8, the control gate electrodes 7b may also be formed for every two normal gate electrodes 7a. Although it is not illustrated, the control gate electrodes 7b may also be formed for every three normal gate electrodes 7a or every four normal gate electrodes 7a. Furthermore, for example, in the direction perpendicular to the extending direction, the normal gate electrodes 7a may also be formed together on one side and the control gate electrodes 7b may also be formed together on the other side. In other words, as long as a part of a plurality of gate electrodes is formed as the control gate electrode 7b, holes can be previously pulled put by appropriately adjusting the voltage applied to the control gate electrodes 7b.

In the above-described first embodiment, an example in which the first conductivity-type is set to P type and the second conductivity-type is set to N type has been described. However, the first conductivity type may also be set to N type and the second conductivity type may also be set to P type.

Furthermore, in the above-described first embodiment, an N type cathode layer may be disposed adjacent to the P⁺ type collector layer 1, and the N⁻ type drift layer 3 may be formed above the P⁺ type collector layer 1 and the N type cathode layer. In other words, the present disclosure can be applied to a semiconductor device in which a so-called reverse-conducting (RC)-IGBT, in which a region where the P⁺ type collector layer 1 is formed is set to an IGBT region and a region where the cathode layer is formed is set to a diode region, is formed. In this case, the P⁺ type collector layer 1 and the N type cathode layer may be formed in a lattice pattern.

1. A semiconductor device comprising:
a collector layer of a first conductivity-type;
a drift layer of a second conductivity-type formed above the collector layer;
a base layer of the first conductivity-type formed above the drift layer;
a plurality of trenches penetrating through the base layer to reach the drift layer and extending in a predetermined direction;
a plurality of gate insulation layers respectively formed on wall surfaces of the trenches;
a plurality of gate electrodes respectively formed on the gate insulation layers, the gate electrodes including the gate electrodes in a first group and the gate electrodes in a second group;
a plurality of emitter layers of the second conductivity-type formed at side portions of the trenches in a surface portion of the base layer;
an emitter electrode electrically connected with the emitter layers;
a collector electrode electrically connected with the collector layer;
a first gate pad connected with the gate electrodes in the first group; and
a second gate pad connected with the gate electrodes in the second group,
wherein electric current flows between the emitter electrode and the collector electrode when a turn-on voltage with which inversion layers are formed at portions in the base layer in contact with the gate insulation layers is applied to the gate electrodes,
wherein the gate electrodes in the first group and the gate electrodes in the second group are controllable independently from each other through the first gate pad and the second gate pad, and
wherein, when turning off, after a turn-off voltage with which the inversion layers are not formed is applied to the gate electrodes in the second group, a turn-off voltage with which the inversion layer are not formed is applied to the gate electrodes in the first group.

2. The semiconductor device according to claim 1,
wherein the gate electrodes in the second group are applied with a negative voltage as the turn-off voltage.

3. The semiconductor device according to claim 1,
wherein the gate electrodes in the first group and the gate electrodes in the second group are alternately arranged in a direction perpendicular to the predetermined direction.

4. The semiconductor device according to claim 1, further comprising
a cathode layer of a second conductivity-type disposed adjacent to the collector layer, wherein the drift layer is formed above the collector layer and the cathode layer.
